(19) United States
(12) Patent Application Publication
(10) Pub. No.: US 2015/0295001 A1
(43) Pub. Date: Oct. 15, 2015

(54) IMAGE SENSOR AND METHOD FOR FABRICATING THE SAME

(71) Applicant: SK hynix Inc., Gyeonggi-do (KR)

(72) Inventors: Chung-Seok CHOI, Gyeonggi-do (KR); Dong-Hyun WOO, Gyeonggi-do (KR); Jong-Chae KIM, Gyeonggi-do (KR)

(21) Appl. No.: 14/556,962

(22) Filed: Dec. 1, 2014

(30) Foreign Application Priority Data
Apr. 14, 2014 (KR) 10-2014-0044243

(51) Int. Cl. H01L 27/146; H01L 31/18; H01L 31/0224

(52) U.S. Cl. CPC H01L 27/14621; H01L 27/14685; H01L 31/022466; H01L 31/1884

(57) ABSTRACT

An image sensor includes: a substrate including a photoelectric conversion region; a charge control layer overlapping with the photoelectric conversion region that is formed over the substrate; an inter-layer dielectric layer including lines that are formed over the charge control layer; and color filters and a light condensing pattern formed over the inter-layer dielectric layer to correspond to the photoelectric conversion region.

### CROSS-REFERENCE TO RELATED APPLICATIONS

The present application claims priority of Korean Patent Application No. 10-2014-0044243, filed on Apr. 14, 2014, which is incorporated herein by reference in its entirety.

### BACKGROUND

1. Field

Exemplary embodiments of the present invention relate to a semiconductor device fabrication technology, and more particularly, to an image sensor including a charge control layer and a method for fabricating the same.

2. Description of the Related Art

An image sensor is a device that converts optical images into electric signals. Image sensors are divided into Charge Coupled Device (CCD) image sensors and Complementary Metal Oxide Semiconductor (CMOS) image sensors (CIS). An image sensor includes a plurality of pixels and each pixel outputs a pixel signal corresponding to incident light. Each pixel accumulates photocharges corresponding to the incident light through a photoelectric conversion element, which is represented by a photodiode, and outputs pixel signals based on the accumulated photocharges.

Dark current, from charges generated in the photoelectric conversion element (located on the surface of the substrate), creates noise in the pixel signals and deteriorates the characteristics of the image sensor.

### SUMMARY

An embodiment of the present invention is directed to an image sensor capable of preventing dark current from being generated on the surface of a substrate, and a method for fabricating such an image sensor.

In accordance with an embodiment of the present invention, an image sensor includes: a substrate including a photoelectric conversion region; a charge control layer overlapping with the photoelectric conversion region that is formed over the substrate; an inter-layer dielectric layer including lines that are formed over the charge control layer; and color filters and a light condensing pattern formed over the inter-layer dielectric layer to correspond to the photoelectric conversion region.

The charge control layer may include a transparent electrode. The charge control layer may include a graphene layer.

The charge control layer may further include contacts coupled with the lines.

The image sensor may further include: an interface layer between the substrate and the charge control layer.

In accordance with another embodiment of the present invention, an image sensor may include: a substrate including a photoelectric conversion region; a charge control layer overlapping with the photoelectric conversion region that is formed over the substrate; an inter-layer dielectric layer including lines that are formed over the charge control layer; and color filters and a light condensing pattern formed over the inter-layer dielectric layer to correspond to the photoelectric conversion region.

The charge control layer may include a transparent electrode. The charge control layer may include a graphene layer.

The image sensor may further include: an interface layer over a profile of the substrate before the forming of the charge control layer.

In accordance with the other embodiment of the present invention, an image sensor may include: a substrate including an electromagnetic wave conversion region; a means of removing electrons that constitute noise in the image sensor using an applied voltage; an inter-layer dielectric layer including lines that are formed above the substrate; an electromagnetic wave filter formed above the substrate to correspond to the electromagnetic wave conversion region; and an electromagnetic wave condensing pattern formed above the inter-layer dielectric layer.

The means of removing electrons that constitute noise in the image sensor may include a charge control layer.

The charge control layer at least partially may overlap with the photoelectric conversion region when viewing the sensor from a direction substantially perpendicular to a plane of the substrate. The charge control layer may include a transparent electrode. The charge control layer may include a graphene layer. The charge control layer further may include a contact coupled with a line.

### BRIEF DESCRIPTION OF THE DRAWINGS

FIG. 1 is a circuit diagram illustrating a unit pixel of an image sensor in accordance with an embodiment of the present invention.

FIG. 2 shows a layout of a unit pixel of an image sensor in accordance with an embodiment of the present invention.

FIG. 3 is a cross-sectional view illustrating an image sensor in accordance with an embodiment of the present invention.

FIGS. 4A to 4C are cross-sectional views illustrating a method for fabricating an image sensor in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on”a substrate, it not only refers to a case where the first layer is formed directly on the second layer or the substrate but also a case where a third layer exists between the first layer and the second layer or the substrate.

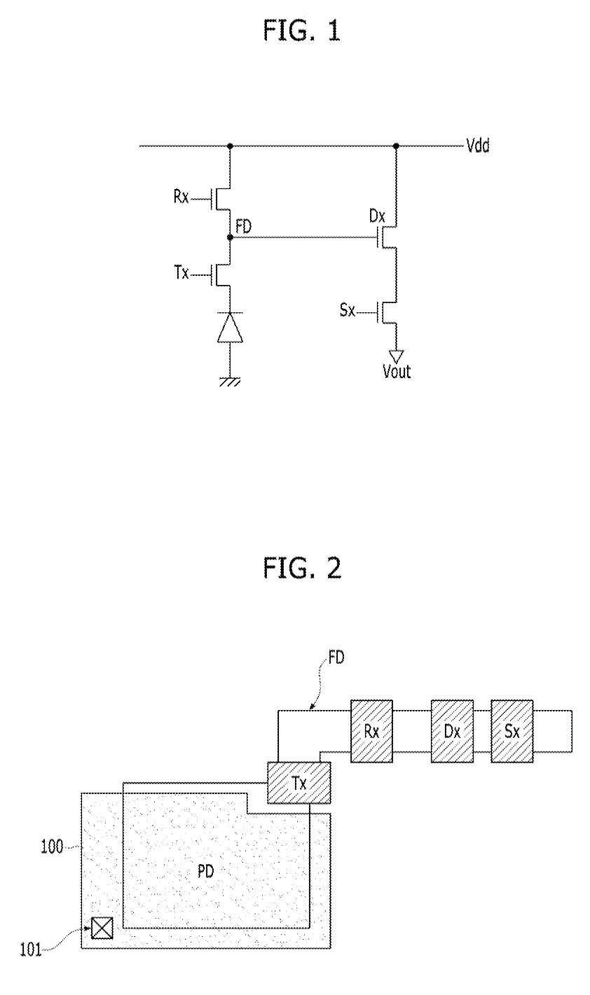

FIG. 1 is a circuit diagram illustrating a unit pixel of an image sensor in accordance with an embodiment of the present invention. FIG. 2 shows a layout of a unit pixel of an image sensor in accordance with an embodiment of the present invention.

Referring to FIGS. 1 and 2, a unit pixel of an image sensor in accordance with an embodiment of the present invention may include a photodiode PD, a transfer transistor Tx, a floating diffusion region FD, a reset transistor Rx, a drive transistor Dx, and a selection transistor Sx. Particularly, the unit pixel of the image sensor in accordance with an embodiment of the present invention may include a charge control layer 100 overlapping with the photodiode, which is the photoelectric conversion region.

The photoelectric conversion region that receives(fight energy and generates and accumulates photocharges may include a photodiode PD.

The transfer transistor Tx transfers the charges, or photoelectric current, accumulated by the photodiode PD to the floating diffusion region FD in response to a transfer control signal inputted into a gate.

The floating diffusion region FD receives the charges generated by the photodiode PD through the transfer transistor Tx and stores the received charges.

The reset transistor Rx is coupled between a power source voltage Vdd and the floating diffusion region FD, and resets the floating diffusion region FD by draining the charges stored in the floating diffusion region FD to the power source voltage Vdd in response to a reset signal RST.

The drive transistor Dx serves as a source follower buffer amplifier, and buffers a signal corresponding to the charges which are stored in the floating diffusion region FD.

The selection transistor Sx performs an addressing function and a switching function for selecting a unit pixel.

The charge control layer 100 removes dark current from the substrate through recombination. The charge control layer 100 may include a transparent electrode. For example, the charge control layer 100 may include a graphene layer.

The charge control layer 100 may include contacts that are coupled with lines so that a voltage is applied thereto.

The charge control layer 100 controls the dark current source using the following method. First, when the transfer transistor Tx is off, a negative voltage may be applied to the charge control layer 100. The negative voltage may be controlled in a range suitable to allow the flow of electrons to the floating diffusion region FD while the transfer transistor Tx is on. Also, as the negative voltage is applied to the charge control layer 100, positive electric charges are induced on the surface of the substrate and the depletion layer of the photoelectric conversion region is increased. As a result, the electrons remaining that constitute the dark current source are transferred to the substrate to be removed through recombination.

When the transfer transistor Tx is on, no voltage is applied to the charge control layer 100. Thus, the accumulated electrons may be transferred to the surface of the substrate after the transfer transistor Tx is turned on.

As described above, the present embodiment of the present invention may prevent the generation of dark current and improve the characteristics of the substrate by removing the electrons (or charges), which constitute the dark current source in the substrate, by an applied voltage.

FIG. 3 is a cross-sectional view illustrating an image sensor in accordance with an embodiment of the present invention.

Referring to FIG. 3, an isolation layer (not shown) for isolating a photoelectric conversion region 12 from the neighboring pixels is formed over a substrate 11 having a plurality of pixels. An interface layer 13 and a charge control layer 14 are stacked over the profile of the substrate 11. Also, an inter-layer dielectric layer 15 including a signal generation circuit 16 is formed over the charge control layer 14. Note, numeral “16” in the drawings represent both the signal generation circuit 16 and the various metal lines 16 used to conduct current and transmit signals. In the drawing of the present embodiment, the reference numeral ‘16’ substantially represents the multiple layers of metal lines 16. However, the reference numeral ‘16’ is used to represent the signal generation circuit 16, hereafter. A light condensing pattern 18 and color filters 17 corresponding to the photoelectric conversion region 12 are formed over the inter-layer dielectric layer 15.

The substrate 11 may include a semiconductor substrate. The semiconductor substrate may be of a monocrystalline state, and the semiconductor substrate may include a silicon-containing material. In short, the substrate 11 may include a monocrystalline silicon-containing material. For example, the substrate 11 may be a bulk silicon substrate, or a Silicon On Insulator (SOI) substrate including a silicon epitaxial layer.

The photoelectric conversion region 12 may include a plurality of photoelectric conversion elements (not shown) that overlap with each other vertically, and each of the photoelectric conversion elements may be a photodiode including an N-type impurity region and a P-type impurity region. The photoelectric conversion region 12 may penetrate through the substrate 11 by contacting with both the front side and rear side of the substrate 11. Also, the photoelectric conversion region 12 may contact the front side of the substrate 11 while being spaced apart from the rear side of the substrate 11 by a predetermined gap.

The interface layer 13 may insulate the substrate 11 from the charge control layer 14. The interface layer 13 may include an insulating material. The interface layer 13 may include an insulating material selected from the group including a nitride, an oxide, and a high K oxide.

The charge control layer 14 may remove electrons that are the source of dark current in the substrate 11 and in the photoelectric conversion region 12. The charge control layer 14 may include a transparent electrode. For example, the charge control layer 14 may include a graphene layer. A graphene layer has light transmissibility of approximately 98%. Therefore, the graphene layer makes it possible to form a charge control layer 14 capable of controlling electrons even in a front side illumination image sensor while minimizing loss of light, and to form the charge control layer 14 over the profile of the photoelectric conversion region 12.

The charge control layer 14 may include contacts 101 (refer to FIG. 2) coupled with lines so that a voltage may be applied thereto. However, the positions of the contacts and the size of the charge control layer 14 are not limited to the layout of FIG. 2, and the size and shape of the charge control layer 14 and the positions of the contacts may be modified.

The inter-layer dielectric layer 15 may include one or more materials selected from the group including an oxide, a nitride and an oxynitride. The signal generation circuit 16 formed inside the inter-layer dielectric layer 15 may include a plurality of transistors (not shown), multiple layers of metal lines 16, and contact plugs (not shown) that couple the transistors (not shown) and the multiple layers of metal lines 16 with each other. The signal generation circuit generates (or outputs) pixel signals (or electrical signals) corresponding to the photocharges generated in the photoelectric conversion region 12.

The color filters 17 may be formed to correspond to the photoelectric conversion region 12. To be specific, red, green and blue filters may be formed corresponding to red (R), green (G) and blue (B) pixels of the photoelectric conversion region 12, or when an image sensor includes an infrared ray photoelectric conversion region, an infrared filter corresponding to an infrared ray receiving device may be formed.

The light condensing pattern 18 may include a microlens.

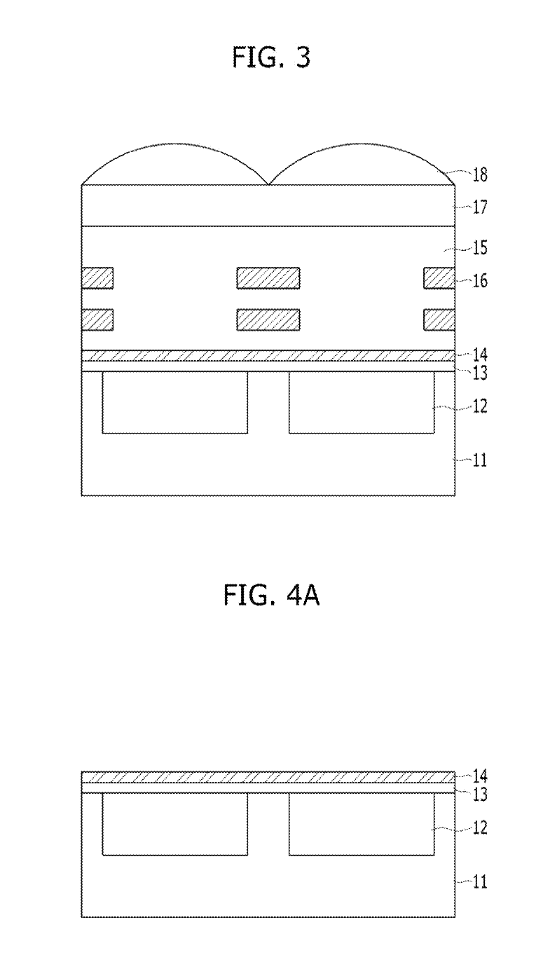

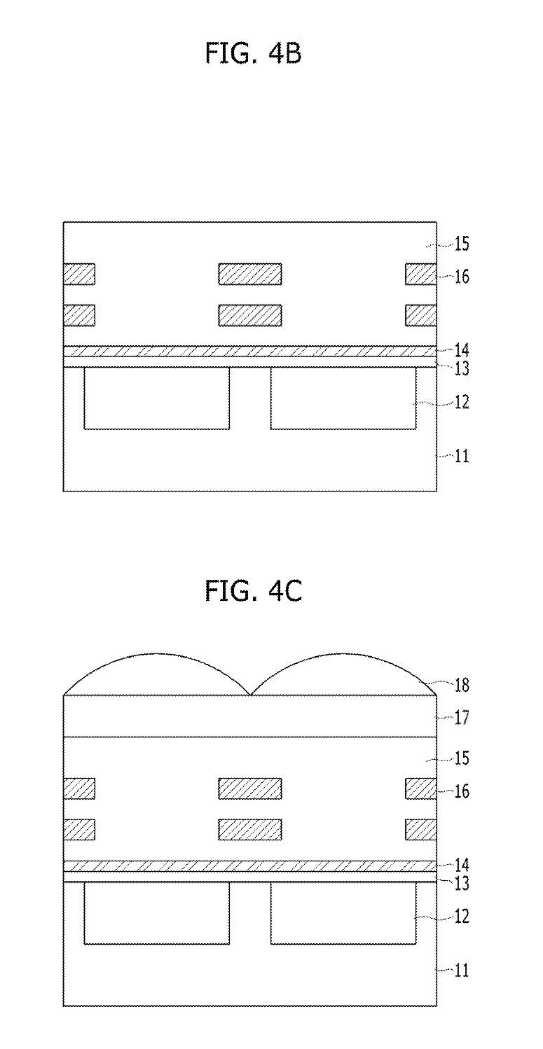

FIGS. 4A to 4C are cross-sectional views illustrating a method for fabricating an image sensor in accordance with an embodiment of the present invention. Since FIGS. 4A to 4C describe a method for fabricating the image sensor shown in FIG. 3, the same reference numerals appearing in FIG. 3 will be used.

Referring to FIG. 4A, a substrate 11 where a plurality of pixels are defined is prepared. The substrate 11 may include a semiconductor substrate. The semiconductor substrate may be of a monocrystalline state, and the semiconductor substrate may include a silicon-containing material. In short, the substrate 11 may include a monocrystalline silicon-containing material. For example, the substrate 11 may be a bulk silicon substrate, or a Silicon On Insulator (SOI) substrate including a silicon epitaxial layer.

Subsequently, an isolation region (not shown) may be formed over the substrate 11 along the boundary area where the pixels contact each other. The isolation region (not shown) may be formed through a Shallow Trench Isolation (STI) process where isolation trenches are formed in the substrate 11 and the isolation trenches are gap-filled with an insulating material.

Subsequently, a photoelectric conversion region 12 may be formed in the substrate 11. The photoelectric conversion region 12 may include a plurality of photoelectric conversion elements (not shown) that overlap with each other vertically, and each of the photoelectric conversion elements may be a photodiode including an N-type impurity region and a P-type impurity region. The photodiode may be formed through an impurity ion-implantation process.

Subsequently, an interface layer 13 may be formed over the substrate 11. The interface layer 13 may insulate the substrate 11 from a charge control layer 14, which is to be formed in the subsequent process. The interface layer 13 may include an insulating material. The interface layer 13 may include an insulating material selected from the group including a nitride, an oxide, and a high K oxide.

Subsequently, a charge control layer 14 may be farmed over the interface layer 13. The charge control layer 14 may remove electrons that act as a dark current source in the substrate 11 and/or the photoelectric conversion region 12.

The charge control layer 14 may include a transparent electrode. For example, the charge control layer 14 may include a graphene layer. A graphene layer has a light transmissibility of approximately 98%. Therefore, the graphene layer makes it possible to form a charge control layer 14 capable of controlling electrons even in a front side illumination image sensor while minimizing loss of light, and to form the charge control layer 14 over the photoelectric conversion region 12. The graphene layer may be formed in a variety of methods, such as a solution method using spin coating or a Chemical Vapor Deposition (CVD) process.

Referring to FIG. 4B, an inter-layer dielectric layer 15 including a signal generation circuit 16 may be formed over the charge control layer 14. The inter-layer dielectric layer 15 may include one or more materials selected from the group including an oxide, a nitride and an oxynitride. The inter-layer dielectric layer 15 may have a multi-layer structure. The signal generation circuit 16 generates (or outputs) pixel signals (or electrical signals) corresponding to the photocharges generated in the photoelectric conversion region 12. The signal generation circuit 16 may include multiple transistors such as a transfer transistor Tx, a selection transistor Sx, a reset transistor Rx, and an drive transistor Dx.

Although not illustrated, the method for fabricating the image sensor may further include a process of opening the substrate 11 by etching the charge control layer 14 and the interface layer 13 of a gate forming region, and forming a gate insulation layer (not shown) and a gate pattern (not shown) over the open substrate 11 before the formation of the inter-layer dielectric layer 15.

Referring to FIG. 4C color filters 17 may be formed over the inter-layer dielectric layer 15. The color filters 17 may be formed to correspond to the photoelectric conversion region 12. To be specific, red, green and blue filters may be formed corresponding to red (R), green (G) and blue (B) pixels of the photoelectric conversion region 12. The scope of the present invention is not limited to this embodiment, and when an image sensor includes an infrared ray photoelectric conversion region (or other type of electromagnetic wave conversion region, including x-rays, UV rays, etc.), an infrared filter (or other E-M wave filter) corresponding to an infrared ray receiving device (or other E-M wave receiving device) may be formed.

Subsequently, a light condensing pattern 18 may be formed over the color filters 17. The light condensing pattern 18 may include a microlens. Before the formation of the light condensing pattern 18, a planarization layer (not shown) may be additionally formed.

Subsequently, the fabrication of the image sensor may be completed through known fabrication technology.

According to an embodiment of the present invention, the charges that constitute dark current may be controlled by forming a charge control layer in above a photoelectric conversion region or in the upper portion of a photoelectric conversion region.

While the present invention has been described with respect to the specific embodiments, it will be apparent to those skilled in the art that various changes and modifications may be made without departing from the spirit and scope of the invention as defined in the following claims.

What is claimed is:

1. An image sensor, comprising:
a substrate including a photoelectric conversion region;
a charge control layer overlapping with the photoelectric conversion region that is formed over the substrate;
an inter-layer dielectric layer including lines that are formed over the charge control layer; and
color filters and a light condensing pattern formed over the inter-layer dielectric layer to correspond to the photoelectric conversion region.

2. The image sensor of claim 1, wherein the charge control layer includes a transparent electrode.

3. The image sensor of claim 1, wherein the charge control layer includes a graphene layer.

4. The image sensor of claim 1, wherein the charge control layer further includes contacts coupled with the lines.

5. The image sensor of claim 1, further comprising:
an interface layer between the substrate and the charge control layer.

6. A method for fabricating an image sensor, comprising:
forming a photoelectric conversion region in a substrate;
forming a charge control layer overlapping with the photoelectric conversion region formed over the substrate;
forming an inter-layer dielectric layer including lines over the charge control layer; and
forming color filters and a light condensing pattern over the inter-layer dielectric layer to correspond to the photoelectric conversion region.

7. The method of claim 6, wherein the charge control layer includes a transparent electrode.

8. The method of claim 6, wherein the charge control layer includes a graphene layer.

9. The method of claim 6, further comprising:
forming an interface layer over a profile of the substrate before the forming of the charge control layer.

10. An image sensor, comprising:
a substrate including an electromagnetic wave conversion region;
a means of removing electrons that constitute noise in the image sensor using an applied voltage;
an inter-layer dielectric layer including lines that are formed above the substrate;
an electromagnetic wave filter formed above the substrate to correspond to the electromagnetic wave conversion region; and
an electromagnetic wave condensing pattern formed above the inter-layer dielectric layer.

11. The image sensor of claim 10, wherein the means of removing electrons that constitute noise in the image sensor includes a charge control layer.

12. The image sensor of claim 11, wherein the charge control layer at least partially overlaps with the photoelectric conversion region when viewing the sensor from a direction substantially perpendicular to a plane of the substrate.

13. The image sensor of claim 12, wherein the charge control layer includes a transparent electrode.

14. The image sensor of claim 13, herein the charge control layer includes a graphene layer.

15. The it age sensor of claim 14, wherein the charge control layer further includes a contact coupled with a line.
